(19) United States
(12) Patent Application Publication
(10) Pub. No.: US 2026/0047440 A1
(43) Pub. Date: Feb. 12, 2026

(54) SEMICONDUCTOR PACKAGE INCLUDING A SHIELD AND METHOD OF MANUFACTURING THE SEMICONDUCTOR PACKAGE

(71) Applicant: SAMSUNG ELECTRONICS CO., LTD., SUWON-SI (KR)

(72) Inventors: BYOUNG-GUG MIN, Suwon-si (KR); SEUNGLO LEE, Suwon-si (KR); JONGHO LEE, Suwon-si (KR); DONGHUN HAN, Suwon-si (KR)

(21) Appl. No.: 19/078,351

(22) Filed: Mar. 13, 2025

(30) Foreign Application Priority Data
Aug. 8, 2024 (KR) 10-2024-0106410

(51) Int. Cl. H01L 23/60; H01L 21/56; H01L 21/683; H01L 23/00; H01L 23/13; H01L 23/31

(52) U.S. Cl. CPC H01L 23/60; H01L 23/13; H01L 21/561; H01L 21/6835; H01L 23/3128; H01L 24/05; H01L 24/45; H01L 24/48; H01L 24/96; H01L 24/97; H01L 2224/05624; H01L 2224/05639; H01L 2224/05644; H01L 2224/05647; H01L 2224/05655; H01L 2224/05657; H01L 2224/05664; H01L 2224/05666; H01L 2224/05669; H01L 2224/05671; H01L 2224/45124; H01L 2224/45139; H01L 2224/45144; H01L 2224/45147; H01L 2224/45155; H01L 2224/45157; H01L 2224/45164; H01L 2224/45166; H01L 2224/45171; H01L 2224/48091; H01L 2224/48227; H01L 2224/96; H01L 2224/97; H01L 2924/1431

(57) ABSTRACT

A semiconductor package includes: a package substrate including a first substrate region and a second substrate region, wherein the first substrate region at least partially surrounds the second substrate region; a semiconductor chip disposed on the package substrate; a mold provided on the package substrate and covering the semiconductor chip; and a shield provided on the mold and the package substrate, wherein a thickness of the first substrate region is smaller than a thickness of the second substrate region.

### CROSS-REFERENCE TO RELATED APPLICATION

The application claims priority under 35 U.S. C. § 119 to Korean Patent Application No. 10-2024-0106410, filed on Aug. 8, 2024, in the Korean Intellectual Property Office, the disclosure of which is incorporated by reference herein in its entirety.

### TECHNICAL FIELD

The present inventive concept relates generally to a semiconductor package and a method for manufacturing a semiconductor package, and more particularly, to a semiconductor package including a shield and a method for manufacturing the semiconductor package.

### DISCUSSION OF THE RELATED ART

A semiconductor package is an implementation of an integrated circuit chip, designed to facilitate its use in electronic devices. A semiconductor package is formed by mounting a semiconductor chip on a printed circuit board (PCB) and electrically connecting them to each other by using bonding wires, bumps, and/or pads. With the development of the electronics industry, various studies are being conducted to increase the reliability and durability of semiconductor packages.

### SUMMARY

According to exemplary embodiments of the present inventive concept, a semiconductor package includes: a package substrate including a first substrate region and a second substrate region, wherein the first substrate region at least partially surrounds the second substrate region; a semiconductor chip disposed on the package substrate; a mold provided on the package substrate and covering the semiconductor chip; and a shield provided on the mold and the package substrate, wherein a thickness of the first substrate region is smaller than a thickness of the second substrate region.

According to exemplary embodiments of the present inventive concept, a method of manufacturing a semiconductor package includes: forming a plurality of semiconductor chips and a plurality of molds on a preliminary package substrate having a plurality of package regions and a cutting region surrounding the plurality of package regions, wherein the plurality of molds cover the plurality of semiconductor chips; forming a groove in the preliminary package substrate; cutting the preliminary package substrate to form a plurality of preliminary semiconductor packages, each which includes a package substrate; and forming a plurality of shields on the plurality of preliminary semiconductor packages, respectively, wherein each of the plurality of the package substrates includes a first substrate region and a second substrate region, wherein the first substrate region has a first thickness, and the second substrate region has a second thickness that is greater than the first thickness.

In exemplary embodiments of the present inventive concept, the groove is formed across a pair of immediately adjacent package regions, and the cutting region is between the pair of immediately adjacent package regions.

In exemplary embodiments of the present inventive concept, a width of the groove is greater than a width of the cutting region.

In exemplary embodiments of the present inventive concept, forming the plurality of shields on the plurality of preliminary semiconductor packages, respectively, includes: landing the plurality of preliminary semiconductor packages on a carrier; and depositing shield material on the plurality of preliminary semiconductor packages and the carrier.

In exemplary embodiments of the present inventive concept, the carrier includes landing holes into which the plurality of preliminary semiconductor packages are respectively inserted.

In exemplary embodiments of the present inventive concept, from a plan view, a width of the landing holes is smaller than a width of the package substrate.

In exemplary embodiments of the present inventive concept, the method further includes: forming a dummy shield on the carrier, wherein the dummy shield is formed by depositing the shield material on the plurality of preliminary semiconductor packages and the carrier.

In exemplary embodiments of the present inventive concept, the dummy shield includes first dummy shield regions and second dummy shield region, wherein the first dummy shield regions vertically overlap with the preliminary package substrate, and the second dummy shield region is formed between the first dummy shield regions, and each of the first dummy shield regions has a thickness that is smaller than a thickness of the second dummy shield region.

In an exemplary embodiment of the present inventive concept, the thickness of each of the first dummy shield regions is smaller than a thickness of the shield formed on side surfaces of the package substrates.

According to exemplary embodiments of the present inventive concept, a semiconductor package includes: a package substrate including circuit pattern; a semiconductor chip disposed on the package substrate; bonding wires electrically connecting the semiconductor chip and the circuit pattern to each other; a mold provided on the package substrate and covering the semiconductor chip and the bonding wires; external connection terminals provided on the package substrate; and a shield provided on the mold and the package substrate, wherein the package substrate includes a first substrate region and a second substrate region, wherein the first substrate region has a first thickness, and the second substrate region has a second thickness that is greater than the first thickness, and wherein the shield is disposed on a side surface and a bottom surface of the first substrate region, and wherein a thickness of the shield on the bottom surface of the first substrate region is smaller than a thickness of the shield on the side surface of the first substrate region.

According to exemplary embodiments of the present inventive concept, a semiconductor package includes: a package substrate including a first substrate region and a second substrate region that is adjacent to the first substrate region, wherein a thickness of the first substrate region is less than a thickness of the second substrate region; a semiconductor chip disposed on the package substrate; and a shield disposed on the package substrate and covering the semiconductor chip, wherein shield extends along a side surface and a bottom surface of the first substrate region.

### BRIEF DESCRIPTION OF DRAWINGS

The above and other aspects and features of exemplary embodiments of the present inventive concept will be more apparent from the following description taken in conjunction with the accompanying drawings, in which:

FIG. 1 is a perspective view of a semiconductor package according to exemplary embodiments of the present inventive concept.

FIG. 2 is a cross-sectional view taken along line A-A′ of FIG. 1.

FIG. 3 is a cross-sectional view taken along line B-B′ of FIG. 1. FIG. 4A is an enlarged view of portion AA′ of FIG. 2.

FIG. 4B and FIG. 4C are enlarged views corresponding to part AA′ of FIG. 2 for illustrating the formation position of a shield.

FIG. 5 is a flow diagram of a method for manufacturing a semiconductor package according to exemplary embodiments of the present inventive concept.

FIGS. 6, 7, 8, 9 and 10 and 12 are cross-sectional views corresponding to FIG. 2 for explaining the manufacturing method of the semiconductor package of FIG. 5.

FIG. 11 is an enlarged view of portion BB′ of FIG. 10.

FIG. 13 is a cross-sectional view corresponding to line A-A′ of FIG. 1 showing a semiconductor package according to exemplary embodiments of the present inventive concept.

### DETAILED DESCRIPTION OF THE EMBODIMENTS

Hereinafter, exemplary embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, or as “contacting” or “in contact with” another element (or using any form of the word “contact”), there are no intervening elements or layers present.

Exemplary embodiments described herein are example embodiments, and thus, the present inventive concept is not limited thereto, and may be realized in various other forms. Each exemplary embodiment provided in the following description is not excluded from being associated or combined with one or more features of another example or another exemplary embodiment also provided herein or not provided herein but is consistent with the spirit and scope of the present inventive concept. It will be also understood that, even if a certain step or operation of manufacturing an apparatus or structure is described later than another step or operation, the step or operation may be performed later than the other step or operation unless the other step or operation is described as being performed after the step or operation.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Exemplary embodiments of the present inventive concept relate to a semiconductor package and a method for manufacturing the same with increased reliability and reduced defect rates. The semiconductor package may include a package substrate that includes two distinct regions: a first substrate region and a second substrate region. The second substrate region, located centrally, has a greater thickness than the first substrate region, which surrounds the second substrate region. This design helps ensure structural stability and reduces the likelihood of defects, particularly during the manufacturing process and under operating conditions.

According to exemplary embodiments of the present inventive concept, the semiconductor package may include a semiconductor chip, bonding wires that establish electrical connections, a mold to protect internal components, and a shield to guard against electromagnetic interference and static electricity. The shield may be designed with varying thicknesses at different parts of the semiconductor package. For instance, it is thicker on the side surfaces of the package substrate and thinner on the bottom surfaces of the package substrate. This thickness variation may prevent shield separation and minimizes defects during fabrication.

According to exemplary embodiments of the present inventive concept, the manufacturing process begins with forming semiconductor chips and molds on a preliminary package substrate, which may include multiple package regions that are separated by a cutting region. A groove may be formed in the cutting region to create the thinner first substrate region. The substrate is then separated into individual packages. Shields are applied to the mold and package substrate, and a dummy shield may be formed on a carrier during the shield deposition process. This shield and substrate design may ensure that the dummy shield remains on the carrier during separation of the semiconductor packages from the carrier, preventing manufacturing defects.

Exemplary embodiments of the present inventive concept may provide increased reliability of the semiconductor package and a reduced defect rate during both manufacturing and operation. The structured thickness variation within the substrate and shield, along with the manufacturing steps, addresses common challenges in semiconductor packaging. These features may make the semiconductor package more durable.

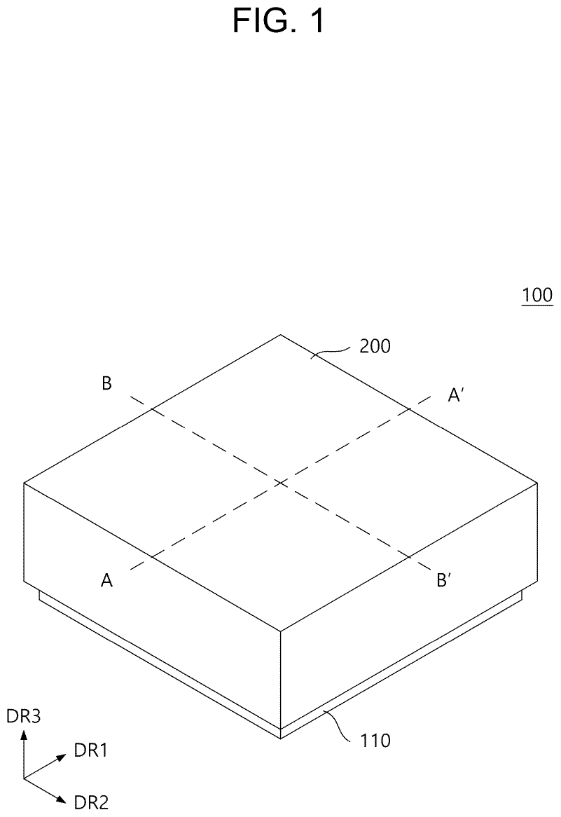

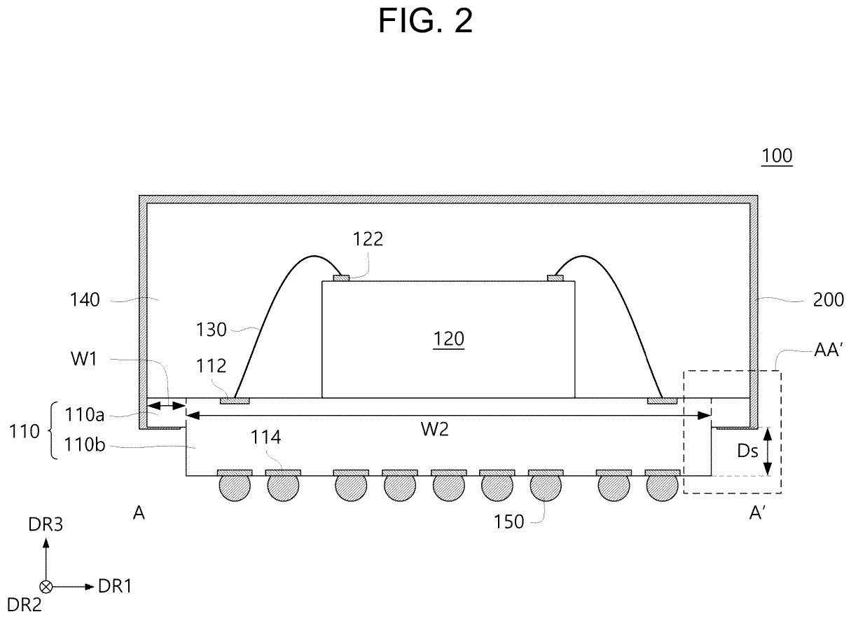

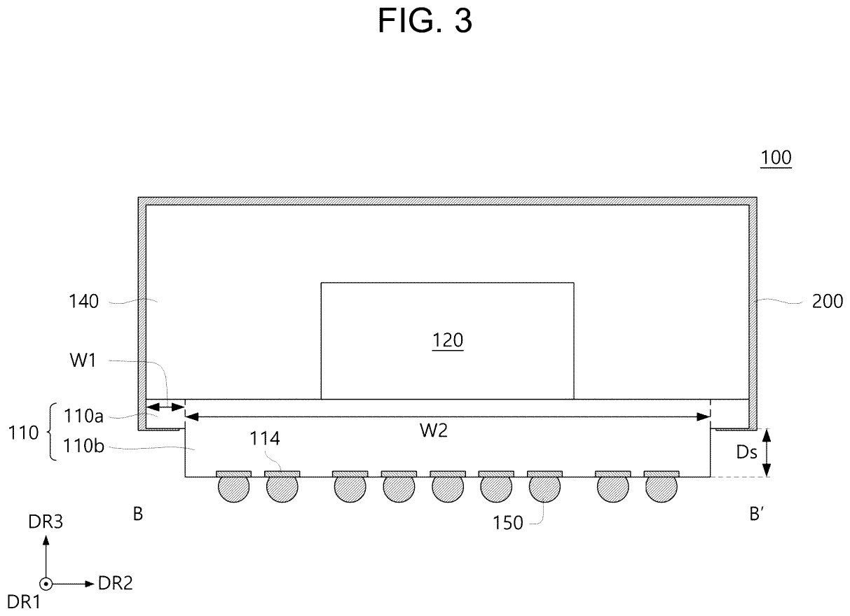

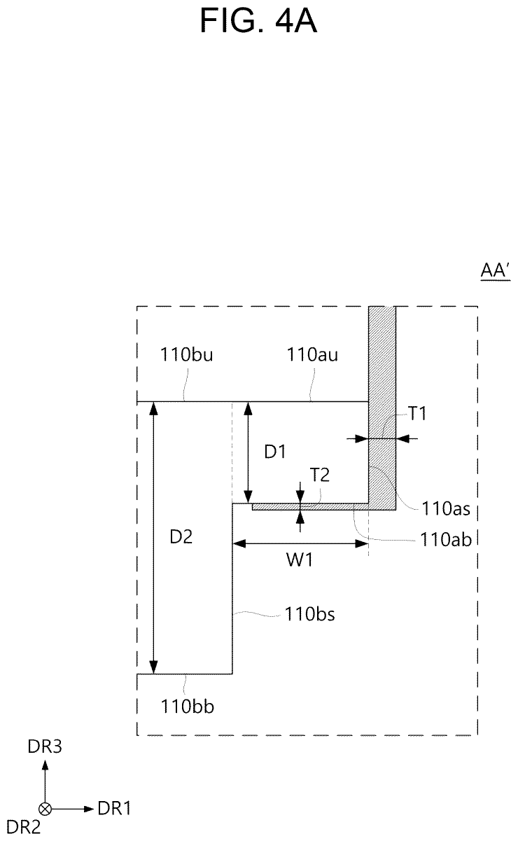

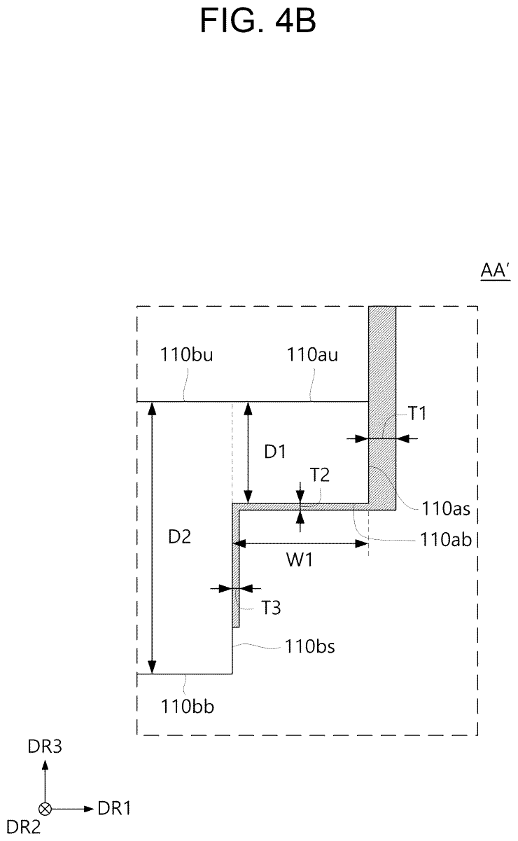

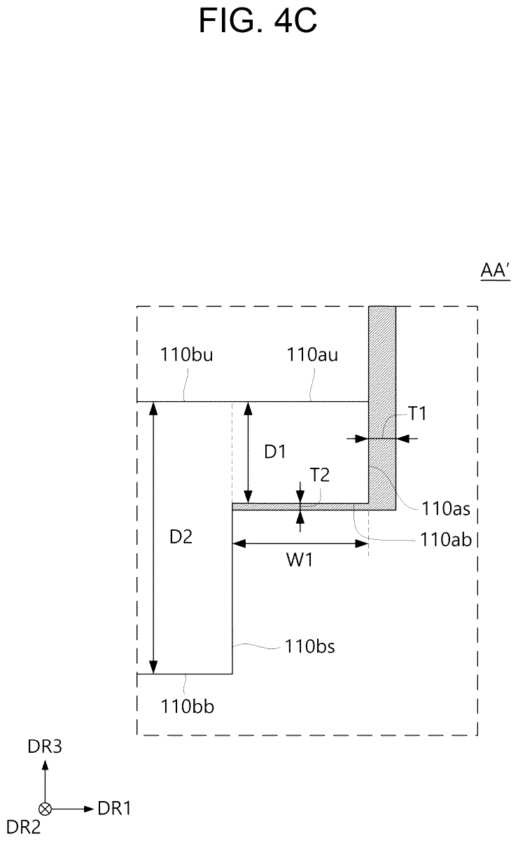

FIG. 1 is a perspective view of a semiconductor package according to exemplary embodiments of the present inventive concept. FIG. 2 is a cross-sectional view taken along line A-A′ of FIG. 1. FIG. 3 is a cross-sectional view taken along line B-B′ of FIG. 1. FIG. 4A is an enlarged view of portion AA′ of FIG. 2. FIG. 4B and FIG. 4C are enlarged views corresponding to part AA′ of FIG. 2 for illustrating the formation position of a shield.

Referring to FIGS. 1 to 3, a semiconductor package 100 may be provided. The semiconductor package 100 may include a package substrate 110. The package substrate 110 may be a printed circuit board (PCB) having circuit patterns. A semiconductor chip 120 may be mounted on a region of the package substrate 110. The bottom surface of the package substrate 110 may provide a region where external connection terminals 150 are arranged. The package substrate 110 may extend in directions parallel to a first direction DR1 and a second direction DR2. The package substrate 110 may have a thickness along a third direction DR3 that is substantially perpendicular to the first direction DR1 and the second direction DR2.

The package substrate 110 may have a first substrate region 110a and a second substrate region 110b. The first substrate region 110a may be an edge region of the package substrate 110. For example, the first substrate region 110a may be a peripheral region. The second substrate region 110b may be at least partially surrounded by the first substrate region 110a. The thickness of the first substrate region 110a may be referred to as a first substrate thickness D1. The first substrate region 110a may have a substantially uniform or substantially constant first substrate thickness D1. The thickness of the second substrate region 110b may be referred to as a second substrate thickness D12. The second substrate region 110b may have a substantially uniform second substrate thickness D12. The first substrate thickness D1 may be smaller than the second substrate thickness D12.

The first substrate region 110a may have a first substrate width W1, and the second substrate region 110b may have a second substrate width W2. The first substrate width W1 may be the width of the first substrate region 110a in a direction away from the second substrate region 110b. For example, the first substrate width W1 may extend in the first direction DR1 and the second direction DR2. From a plan view, the first substrate width W1 may be the distance between an inner boundary and a sidewall (e.g., an outer boundary) of the first substrate region 110a. The inner boundary of the first substrate region 110a may be the boundary adjacent to the second substrate region 110b. For example, the inner boundary of the first substrate region 110a may face the second substrate region 110b and may be connected to the second substrate region 110b. For example, the second substrate width W2 may be defined by the inner boundary of the first substrate region 110a. For example, the second substrate width W2 may extend in the first direction DR1 and the second direction DR2. The outer boundary of the first substrate region 110a may be the boundary that is spaced apart from the second substrate region 110b. As shown in FIG. 2, the first substrate width W1 of the first substrate region 110a may be in the first direction DR1. As shown in FIG. 3, the first substrate width W1 of the first substrate region 110a may extend along the second direction DR2.

The upper surface 110au of the first substrate region 110a and the upper surface 110bu of the second substrate region 110b may be located substantially at the same level. For example, the upper surface 110au of the first substrate region 110a and the upper surface 110bu of the second substrate region 110b may be coplanar. The bottom surface 110ab of the first substrate region 110a may be spaced apart from the bottom surface 110bb of the second substrate region 110b along the third direction DR3. In exemplary embodiments of the present inventive concept, the distance Ds between the bottom surface 110bb of the second substrate region 110b and the bottom surface 110ab of the first substrate region 110a may be about 50 micrometers (μm).

As shown in FIG. 2, the bottom surface 110ab of the first substrate region 110a may have a width along the first direction DR1 and may extend along the second direction DR2. As shown in FIG. 3, the first substrate region 110a may have a width along the second direction DR2 and extend along the first direction DR1. The first substrate region 110a may expose the side surface 110bs of the second substrate region 110b. The side surface 110bs of the second substrate region 110b may be provided below the bottom surface 110ab of the first substrate region 110a. The lower side surface of the second substrate region 110b may extend along the third direction DR3. For example, the lower side surface 110bs of the second substrate region 110b may be substantially perpendicular to the bottom surface 110ab of the first substrate region 110a. However, the present inventive concept is not limited thereto. For example, the lower side surface 110bs of the second substrate region 110b may extend diagonally in a direction that is between the first and third directions DR1 and D3.

The package substrate 110 may include upper pads 112 and lower pads 114. The upper pads 112 may be electrically connected to the semiconductor chip 120. The upper pads 112 may be provided on the upper portion of the package substrate 110. The upper pads 112 may be disposed adjacent to the upper surface of the package substrate 110. For example, the upper pads 112 may be disposed on the second substrate region 110b. The upper pads 112 may be arranged along the first direction DR1, the second direction DR2, or a combination of the first direction DR1 and the second direction DR2.

The lower pads 114 may be electrically connected to the external connection terminals 150. The lower pads 114 may be provided on the lower portion of the package substrate 110. The lower pads 114 may be provided in the second substrate region 110b of the package substrate 110. The lower pads 114 may be disposed adjacent to the bottom surface of the package substrate 110. The lower pads 114 may be arranged along the first direction DR1, the second direction DR2, or a combination of the first direction DR1 and the second direction DR2.

Corresponding upper pads 112 and lower pads 114 may be electrically connected to each other by circuit patterns that are formed in the package substrate 110. Each of the upper pads 112 and lower pads 114 may include electrically conductive materials. For example, each of the upper pads 112 and lower pads 114 may include at least one of gold (Au), silver (Ag), platinum (Pt), aluminum (Al), copper (Cu), palladium (Pd), nickel (Ni), cobalt (Co), chromium (Cr), and/or titanium (Ti).

The semiconductor package 100 may include a semiconductor chip 120. The semiconductor chip 120 may be provided on the package substrate 110. For example, the semiconductor chip 120 may be a logic semiconductor chip or a memory semiconductor chip. One semiconductor chip 120 is shown illustratively. In exemplary embodiments of the present inventive concept, the semiconductor package 100 may include a plurality of semiconductor chips 120. The semiconductor chip 120 may include bonding pads 122 to which bonding wires 130, to be described later, are electrically connected. The bonding pads 122 may include electrically conductive materials. For example, the bonding pads 122 may include at least one of gold (Au), silver (Ag), platinum (Pt), aluminum (Al), copper (Cu), palladium (Pd), nickel (Ni), cobalt (Co), chromium (Cr), and/or titanium (Ti).

The semiconductor package 100 may include bonding wires 130. The bonding wires 130 may be provided between the semiconductor chip 120 and the package substrate 110. For example, the bonding wires 130 may be provided between the bonding pads 122 and the upper pads 112, respectively. One end of the bonding wire 130 may be electrically connected to the bonding pad 122, and the other end may be electrically connected to the upper pad 112. The bonding wires 130 may electrically connect the semiconductor chip 120 and the package substrate 110 to each other. The bonding wires 130 may include electrically conductive materials. For example, the bonding wires 130 may include at least one of gold (Au), silver (Ag), platinum (Pt), aluminum (Al), copper (Cu), palladium (Pd), nickel (Ni), cobalt (Co), chromium (Cr), and/or titanium (Ti).

The semiconductor package 100 may include a mold 140. The mold 140 may be provided on the upper surface of the package substrate 110. The mold 140 may be disposed on the first substrate region 110a and the second substrate region 110b. The mold 140 may be provided across the second substrate region 110b and the first substrate region 110a. The mold 140 may at least partially surround the semiconductor chip 120 and the bonding wires 130. The mold 140 may protect the semiconductor chip 120, the bonding wires 130, and the package substrate 110. For example, the mold 140 may protect the semiconductor chip 120, the bonding wires 130, and the package substrate 110 from an external force. The mold 140 may include electrically insulating materials. For example, the mold 140 may include epoxy molding compound (EMC) or underfill material.

The semiconductor package 100 may include external connection terminals 150. The external connection terminals 150 may be provided on the lower pads 114, respectively. The external connection terminals 150 may be electrically connected to the lower pads 114, respectively. For example, the external connection terminals 150 may be solder balls. In exemplary embodiments of the present inventive concept, the external connection terminals 150 may include conductive bumps, conductive spacers, or pin grid arrays.

The semiconductor package 100 may include a shield 200. The shield 200 may be provided on the mold 140. The shield 200 may extend along the surface of the mold 140 to cover the mold 140. The shield 200 may also cover the semiconductor chip 120, the bonding wires 130, and the package substrate 110. For example, the shield 200 may include a single metal film or a composite film including a metal film and a dielectric film. The metal film may have a single-layer or multi-layer structure. For example, the metal film may include SUS, copper (Cu), nickel (Ni), or combinations thereof. The dielectric film may have a single-layer or multi-layer structure. For example, the dielectric film may include inorganic materials (e.g., aluminum oxide, silicon oxide), polymeric materials (e.g., epoxy, polyurethane), or combinations thereof. In exemplary embodiments of the present inventive concept, the shield 200 may protect the circuits inside the semiconductor package 100 from external electromagnetic interference or static electricity and dissipate heat from the semiconductor package 100 to the outside.

The shield 200 may be provided on the first substrate region 110a. For example, the shield 200 may contact the first substrate region 110a. The shield 200 may extend along the side surface 110as and bottom surface 110ab of the first substrate region 110a. The portion of the shield 200 that is on the side surface 110as of the first substrate region 110a may have a first shield thickness T1. The portion of the shield 200 that is on the bottom surface 110ab of the first substrate region 110a may have a second shield thickness T2. The second shield thickness T2 may be smaller than the first shield thickness T1.

In exemplary embodiments of the present inventive concept, as shown in FIG. 4A, the shield 200 may be provided to cover the side surface 110as and a portion of the bottom surface 110ab of the first substrate region 110a. The shield 200 may expose another portion of the bottom surface 110ab of the first substrate region 110a. The shield 200 may be spaced apart from the side surface 110bs of the second substrate region 110b. The distance Ds between the bottom surface 110bb of the second substrate region 110b and the bottom surface 110ab of the first substrate region 110a and the first substrate width W1 may be determined such that the shield 200 is formed on the side surface 110as and a portion of the bottom surface 110ab of the first substrate region 110a. For example, the distance Ds between the bottom surface 110bb of the second substrate region 110b and the bottom surface 110ab of the first substrate region 110a may be about 50 micrometers (μm), and the first substrate width W1 may be greater than about 540 micrometers (μm).

In exemplary embodiments of the present inventive concept, as shown in FIG. 4B, the shield 200 may be provided to cover the side surface 110as and bottom surface 110ab of the first substrate region 110a, and a portion of the side surface 110bs of the second substrate region 110b. The shield 200 may expose another portion of the side surface 110bs of the second substrate region 110b. The distance Ds between the bottom surface 110bb of the second substrate region 110b and the bottom surface 110ab of the first substrate region 110a and the first substrate width W1 may be determined such that the shield 200 is formed on the side surface 110as and bottom surface 110ab of the first substrate region 110a, and on a portion of the side surface 110bs of the second substrate region 110b. For example, the distance Ds between the bottom surface 110bb of the second substrate region 110b and the bottom surface 110ab of the first substrate region 110a may be about 50 micrometers (μm), and the first substrate width W1 may be greater than about 50 micrometers (μm) and less than about 540 micrometers (μm). The portion of the shield 200 that is formed on the side surface 110bs of the second substrate region 110b may have a third shield thickness T3. The third shield thickness T3 may be smaller than the first shield thickness T1. In exemplary embodiments of the present inventive concept, the third shield thickness T3 may be smaller than the second shield thickness T2. In exemplary embodiments of the present inventive concept, the third shield thickness T3 may be substantially equal to the second shield thickness T2.

In exemplary embodiments of the present inventive concept, as shown in FIG. 4C, the shield 200 may completely cover the bottom surface 110ab of the first substrate region 110a but does not extend along the side surface 110bs of the second substrate region 110b. For example, the distance Ds between the bottom surface 110bb of the second substrate region 110b and the bottom surface 110ab of the first substrate region 110a may be about 50 micrometers (μm), and the first substrate width W1 may be about 540 micrometers (μm).

When the package substrate has a uniform thickness throughout, during the manufacturing process of the semiconductor package 100, the end of the shield 200 may become separated from the package substrate 110. This may result in defects in the semiconductor package.

The present inventive concept can prevent the shield 200 from being separated from the package substrate 110. For example, by providing the portions of the shield 200 that extend along at least one of the bottom surface 110ab of the first substrate region 110a and/or the side surface 110bs of the second substrate region 110b with smaller thicknesses than other portions of the shield 200, separation between the shield 200 and semiconductor package 100 may be prevented. This may also prevent damage to the semiconductor package 100. Accordingly, a semiconductor package 100 with a reduced defect rate can be provided.

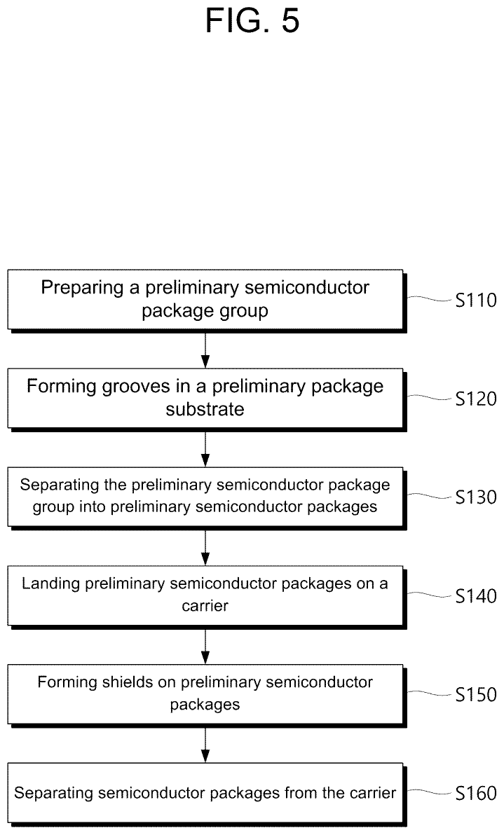

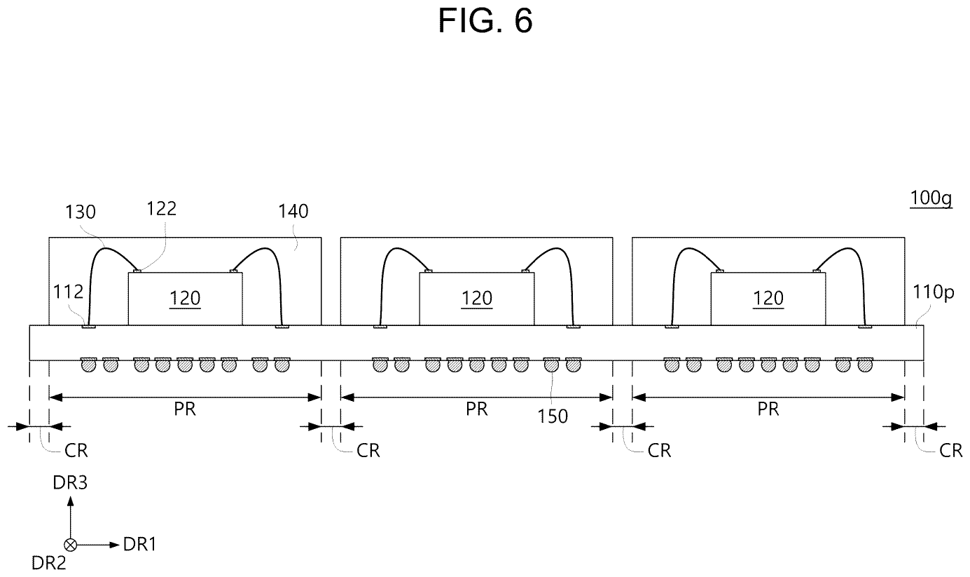

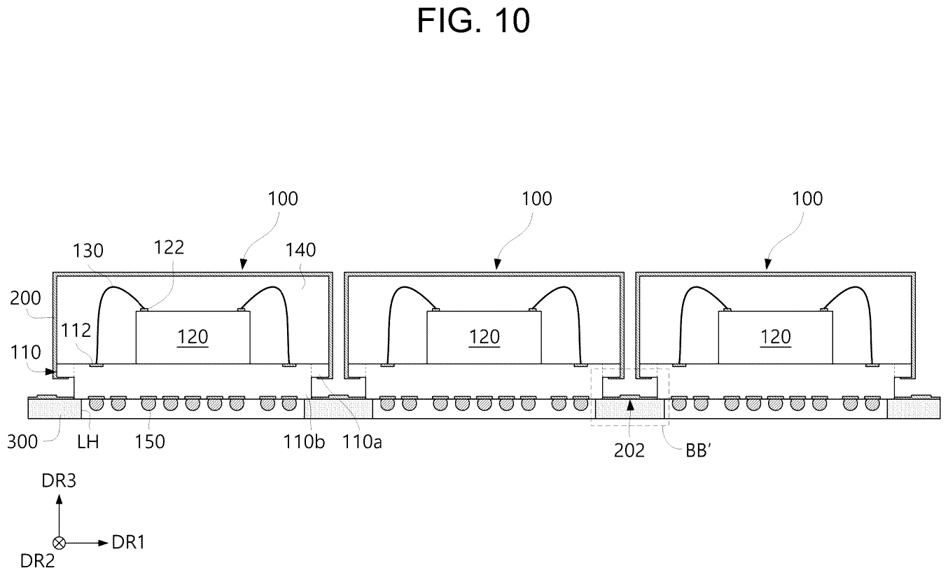

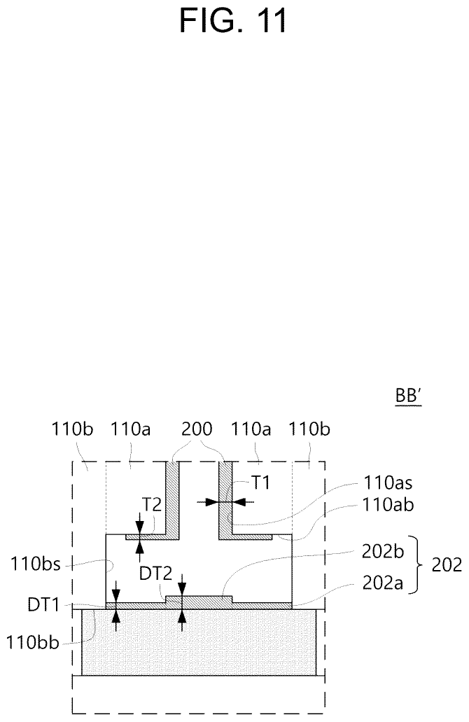

FIG. 5 is a flow diagram of a method for manufacturing a semiconductor package according to exemplary embodiments of the present inventive concept. FIGS. 6 to 10 and 12 are cross-sectional views corresponding to FIG. 2 for explaining the manufacturing method of the semiconductor package of FIG. 5. FIG. 11 is an enlarged view of portion BB′ of FIG. 10.

Referring to FIGS. 5 and 6, a preliminary semiconductor package group 100g may be prepared (S110). The preliminary semiconductor package group 100g may include a preliminary package substrate 110p. The preliminary package substrate 110p may include a plurality of package regions PR and a cutting region CR. The plurality of package regions PR may be regions where semiconductor chips 120 are mounted. The cutting region CR may be a region where the preliminary semiconductor package group 100g is cut. The cutting region CR may at least partially surround each of the plurality of package regions PR. The preliminary package substrate 110p may be a printed circuit board (PCB) having circuit patterns. In exemplary embodiments of the present inventive concept, identical circuit patterns may be formed in each of the package regions PR. The preliminary package substrate 110p may have an upper surface and a lower surface that is opposite to the upper surface. The upper surface of the preliminary package substrate 110p may include regions where semiconductor chips 120 are mounted. The bottom surface of the preliminary package substrate 110p may include regions where external connection terminals 150 are arranged. The preliminary package substrate 110p may extend in directions parallel to the first direction DR1 and the second direction DR2. The preliminary package substrate 110p may have a thickness along the third direction DR3.

The preliminary package substrate 110p may include upper pads 112 and lower pads 114. The upper pads 112 may be electrically connected to the semiconductor chips 120. The upper pads 112 may be provided on the upper portion of the preliminary package substrate 110p. The upper pads 112 may be disposed adjacent to the upper surface of the preliminary package substrate 110p. For example, the upper pads 112 may be disposed in the preliminary package substrate 110p. The upper pads 112 may be arranged along the first direction DR1, the second direction DR2, or a combination of the first direction DR1 and the second direction DR2.

The lower pads 114 may be electrically connected to the external connection terminals 150. The lower pads 114 may be provided on the lower portion of the preliminary package substrate 110p. The lower pads 114 may be disposed adjacent to the bottom surface of the preliminary package substrate 110p. For example, the lower pads 114 may be disposed in the preliminary package substrate 110p. The lower pads 114 may be arranged along the first direction DR1, the second direction DR2, or a combination of the first direction DR1 and the second direction DR2.

Corresponding upper pads 112 and lower pads 114 may be electrically connected to each other through circuit patterns that are formed in the preliminary package substrate 110p. The upper pads 112 and lower pads 114 may include electrically conductive materials. For example, each of the upper pads 112 and lower pads 114 may include at least one of gold (Au), silver (Ag), platinum (Pt), aluminum (Al), copper (Cu), palladium (Pd), nickel (Ni), cobalt (Co), chromium (Cr), and/or titanium (Ti).

The preliminary semiconductor package group 100g may include semiconductor chips 120. The semiconductor chips 120 may be provided on the preliminary package substrate 110p. For example, the semiconductor chips 120 may be logic semiconductor chips or memory semiconductor chips. One semiconductor chip 120 is shown illustratively in each of the package regions PR. In exemplary embodiments of the present inventive concept, a plurality of semiconductor chips 120 may be arranged in each of the package regions PR. Each of the semiconductor chips 120 may include bonding pads 122 to which bonding wires 130 are connected. The bonding pads 122 may include electrically conductive materials. For example, the bonding pads 122 may include at least one of gold (Au), silver (Ag), platinum (Pt), aluminum (Al), copper (Cu), palladium (Pd), nickel (Ni), cobalt (Co), chromium (Cr), and/or titanium (Ti).

The preliminary semiconductor package group 100g may include bonding wires 130. The bonding wires 130 may be provided between the semiconductor chips 120 and the preliminary package substrate 110p. For example, the bonding wires 130 may be provided between the bonding pads 122 and the upper pads 112, respectively. One end of the bonding wire 130 may be electrically connected to the bonding pad 122, and the other end of the bonding wire 130 may be electrically connected to the upper pad 112. The bonding wires 130 may electrically connect the semiconductor chips 120 and the preliminary package substrate 110p to each other. The bonding wires 130 may include electrically conductive materials. For example, the bonding wires 130 may include at least one of gold (Au), silver (Ag), platinum (Pt), aluminum (Al), copper (Cu), palladium (Pd), nickel (Ni), cobalt (Co), chromium (Cr), and/or titanium (Ti).

The preliminary semiconductor package group 100g may include molds 140. The molds 140 may be provided on the upper surface of the preliminary package substrate 110p. The molds 140 may be provided across the second substrate region 110b and the first substrate region 110a. The molds 140 may at least partially surround the semiconductor chips 120 and the bonding wires 130 and may cover the semiconductor chips 120 and the bonding wires 130. The mold 140 may include electrically insulating materials. For example, the molds 140 may include epoxy molding compound (EMC) or underfill material.

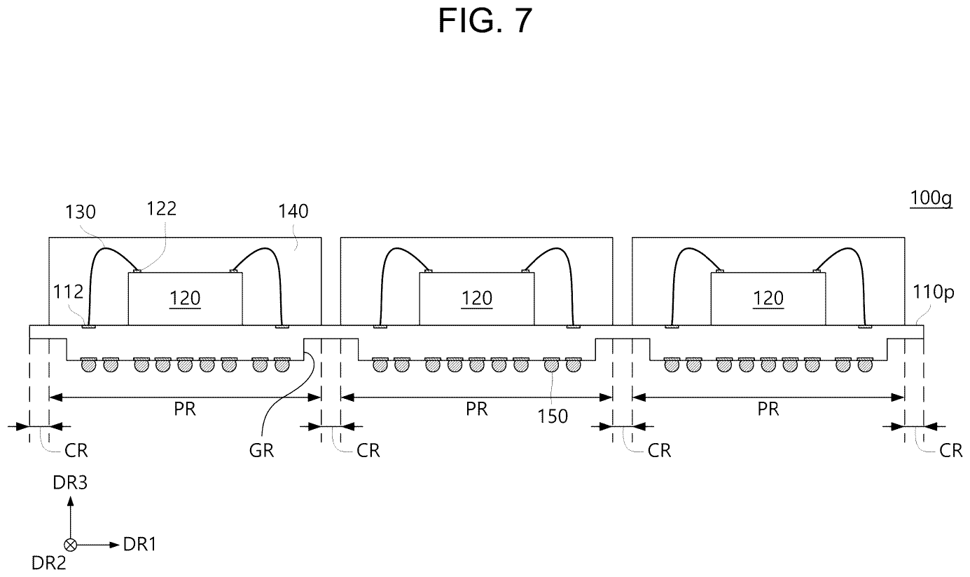

Referring to FIGS. 5 and 7, a groove GR may be formed in the preliminary package substrate 110p (S120). The groove GR may have a width that is greater than a width of the cutting region CR. The groove GR may be formed in the lower portion of the preliminary package substrate 110p. In exemplary embodiments of the present inventive concept, the groove GR may be formed by removing a portion of the bottom surface of the preliminary package substrate 110p to a predetermined height by using a PCB router with a high-speed rotating router bit. In exemplary embodiments of the present inventive concept, the groove GR may be formed by an etching process. The groove GR may extend along the edges of the package regions PR. The groove GR may be formed between a pair of immediately adjacent package regions PR, and the cutting region CR may be between the pair of immediately adjacent package regions PR.

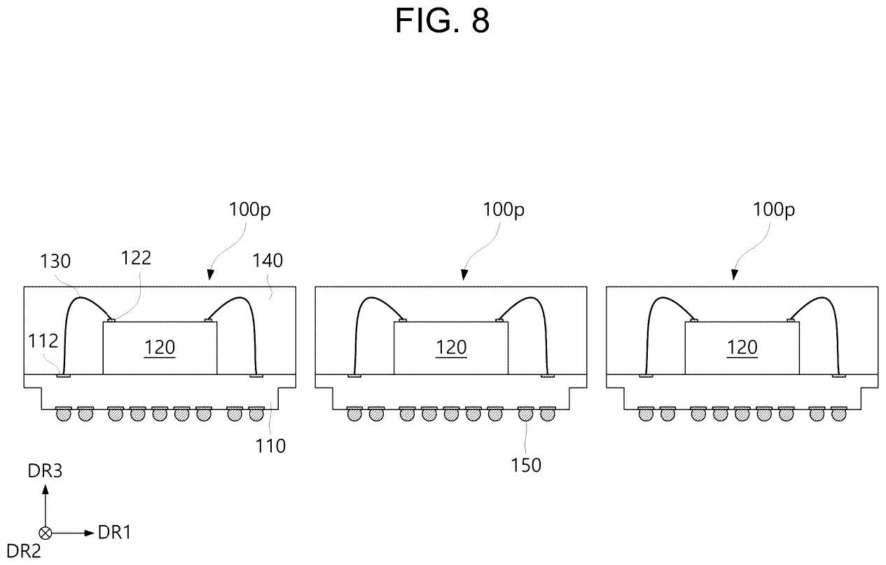

Referring to FIGS. 5 and 8, the preliminary semiconductor package group 100g may be separated into individual preliminary semiconductor packages 100p (S130). The separation process of the preliminary semiconductor package group 100g may include removing the cutting region CR of the preliminary package substrate 110p by using a cutting means. For example, the cutting means may include a PCB router, a V-cut cutter, or a laser cutter. When the cutting means is a PCB router, the PCB router may cut the preliminary package substrate 110p after forming the groove GR in the preliminary package substrate 110p. The preliminary package substrate 110p may be separated into individual package substrates 110. Each of the package substrates 110 may include the first substrate region 110a and the second substrate region 110b described with reference to FIGS. 1 to 4A. The first substrate region 110a may be the region where the groove GR is formed.

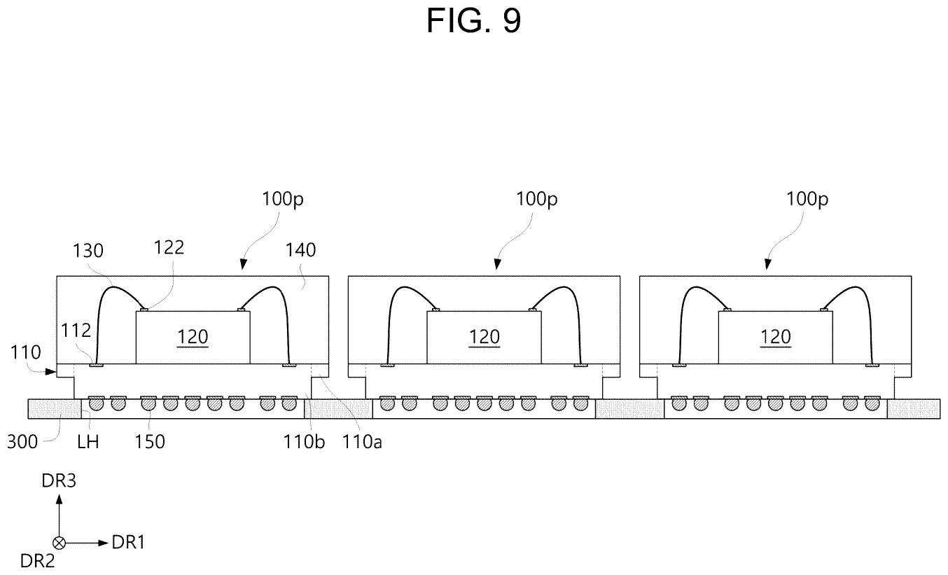

Referring to FIGS. 5 and 9, the preliminary semiconductor packages 100p may be landed on a carrier 300 (S140). The carrier 300 may support the preliminary semiconductor packages 100p. For example, the carrier 300 may include polyimide (PI). The carrier 300 may define landing holes LH. The preliminary semiconductor packages 100p may be provided on the landing holes LH, respectively. For example, external connection terminals 150 of the preliminary semiconductor package 100p may be inserted into the landing holes LH. From a plan view, the landing hole LH may be smaller than the second substrate region 110b. For example, the width of the landing hole LH along the first direction DR1 may be smaller than the second substrate width W2 along the first direction DR1. The width of the landing hole LH along the first direction DR1 may be smaller than the gap between a pair of immediately adjacent grooves GR formed in one package substrate 110 along the first direction DR1. For example, the width of the landing hole LH along the second direction DR2 may be smaller than the second substrate width W2 along the second direction DR2. The width of the landing hole LH along the second direction DR2 may be smaller than the gap between a pair of immediately adjacent grooves GR formed in one package substrate 110 along the second direction DR2. The second substrate regions 110b may contact the carrier 300 around the landing holes LH. Accordingly, the carrier 300 may support the second substrate regions 110b to fix the vertical position of the preliminary semiconductor packages 100p. For example, the vertical position may refer to the direction parallel to gravity.

Referring to FIGS. 5, 10, and 11, shields 200 may be formed on the preliminary semiconductor packages 100p (S150). The preliminary semiconductor packages 100p with the shields 200 formed thereon may be the semiconductor packages 100 described with reference to FIGS. 1 to 4A. Forming the shields 200 may include depositing shield material on the preliminary semiconductor packages 100p. For example, the shield material may be deposited onto the mold 140 and the package substrate 110. For example, depositing the shield material may include sputtering, Physical Vapor Deposition (PVD), Chemical Vapor Deposition (CVD), or Atomic Layer Deposition (ALD). When each of the shields 200 is a single metal layer, the shield material may include metal. For example, the metal may include SUS, copper (Cu), nickel (Ni), or combinations thereof. When each of the shields 200 is multi-layers including at least one dielectric film and at least one metal layer, the shield material may include dielectric material and metal material. For example, the dielectric material may include inorganic materials (e.g., aluminum oxide, silicon oxide), polymeric materials (e.g., epoxy, polyurethane), or combinations thereof.

The shield 200 may be formed to cover the mold 140. The shield 200 may be formed to extend along the side surface 110as and bottom surface 110ab of the first substrate region 110a. The shield 200 formed on the side surface 110as of the first substrate region 110a may have a first shield thickness T1. The shield 200 formed on the bottom surface 110ab of the first substrate region 110a may have a second shield thickness T2. The second shield thickness T2 may be smaller than the first shield thickness T1.

During the formation process of the shields 200, shield material may be deposited on the carrier 300. The shield material layer deposited on the carrier 300 may be referred to as a dummy shield 202. The dummy shield 202 may include first dummy shield regions 202a and second dummy shield regions 202b. The first dummy shield regions 202a may be formed between the first substrate region 110a and the carrier 300, and a second dummy shield region 202b formed between the first dummy shield regions 202a. For example, the first dummy shield regions 202a may overlap with the first substrate regions 110a along the third direction DR3. For example, the second dummy shield region 202b may be exposed between the first substrate regions 110a of neighboring semiconductor packages 100.

The first dummy shield regions 202a may have a first dummy thickness DT1. The second dummy shield region 202b may have a second dummy thickness DT2. The first dummy thickness DT1 may be smaller than the second dummy thickness DT2. The first dummy thickness DT1 may be smaller than the first shield thickness T1. In exemplary embodiments of the present inventive concept, the first dummy thickness DT1 may be substantially equal to or less than the second shield thickness T2.

In exemplary embodiments of the present inventive concept, as shown in FIG. 11, the shield 200 may be provided to cover the side surface 110as and a portion of the bottom surface 110ab of the first substrate region 110a. The shield 200 may expose another portion of the bottom surface 110ab of the first substrate region 110a. The shield 200 may be spaced apart from the side surface 110bs of the second substrate region 110b. The shield 200 may be spaced apart from the dummy shield 202. Another portion of the bottom surface 110ab of the first substrate region 110a and the side surface 110bs of the second substrate region 110b may be exposed between the shield 200 and the dummy shield 202. The distance Ds between the bottom surface 110bb of the second substrate region 110b and the bottom surface 110ab of the first substrate region 110a and the first substrate width W1 may be determined such that the shield 200 is formed on the side surface 110as and a portion of the bottom surface 110ab of the first substrate region 110a. For example, the distance Ds between the bottom surface 110bb of the second substrate region 110b and the bottom surface 110ab of the first substrate region 110a may be about 50 micrometers (μm), and the first substrate width W1 may be greater than about 540 micrometers (μm).

In exemplary embodiments of the present inventive concept, as shown in FIG. 4B, the shield 200 may be provided to cover the side surface 110as and bottom surface 110ab of the first substrate region 110a, and a portion of the side surface 110bs of the second substrate region 110b. For example, the shield 200 may be connected to the dummy shield 202, or the shield 200 may be spaced apart from the dummy shield 202 on the side surface 110bs of the second substrate region 110b. When the shield 200 that is disposed on the side surface of the second substrate region 110b is spaced apart from the dummy shield 202 that is disposed on the carrier 300, another portion of the side surface 110bs of the second substrate region 110b may be exposed between the shield 200 and the dummy shield 202.

The distance Ds between the bottom surface 110bb of the second substrate region 110b and the bottom surface 110ab of the first substrate region 110a and the first substrate width W1 may be determined such that the shield 200 is formed on the side surface 110as and bottom surface 110ab of the first substrate region 110a, and a portion of the side surface 110bs of the second substrate region 110b. For example, the distance Ds between the bottom surface 110bb of the second substrate region 110b and the bottom surface 110ab of the first substrate region 110a may be about 50 micrometers (μm), and the first substrate width W1 may be greater than about 50 micrometers (μm) and less than about 540 micrometers (μm).

The shield 200 formed on the side surface 110bs of the second substrate region 110b may have a third shield thickness T3. The third shield thickness T3 may be smaller than the first shield thickness T1. In exemplary embodiments of the present inventive concept, the third shield thickness T3 may be smaller than the second shield thickness T2. In exemplary embodiments of the present inventive concept, the third shield thickness T3 may be substantially equal to the second shield thickness T2. In exemplary embodiments of the present inventive concept, the first dummy thickness DT1 may be substantially equal to the second shield thickness T2. By utilizing the first, second and third shield thicknesses T1, T2, and T3 as described above, separation between the shield 200 and semiconductor package 100 may be prevented.

In exemplary embodiments of the present inventive concept, as shown in FIG. 4C, the shield 200 may completely cover the bottom surface 110ab of the first substrate region 110a but does not extend onto the side surface 110bs of the second substrate region 110b. For example, another portion of the bottom surface 110ab of the first substrate region 110a and the side surface 110bs of the second substrate region 110b may be exposed between the shield 200 and the dummy shield 202. For example, the distance Ds between the bottom surface 110bb of the second substrate region 110b and the bottom surface 110ab of the first substrate region 110a may be about 50 micrometers (μm), and the first substrate width W1 may be about 540 micrometers (μm).

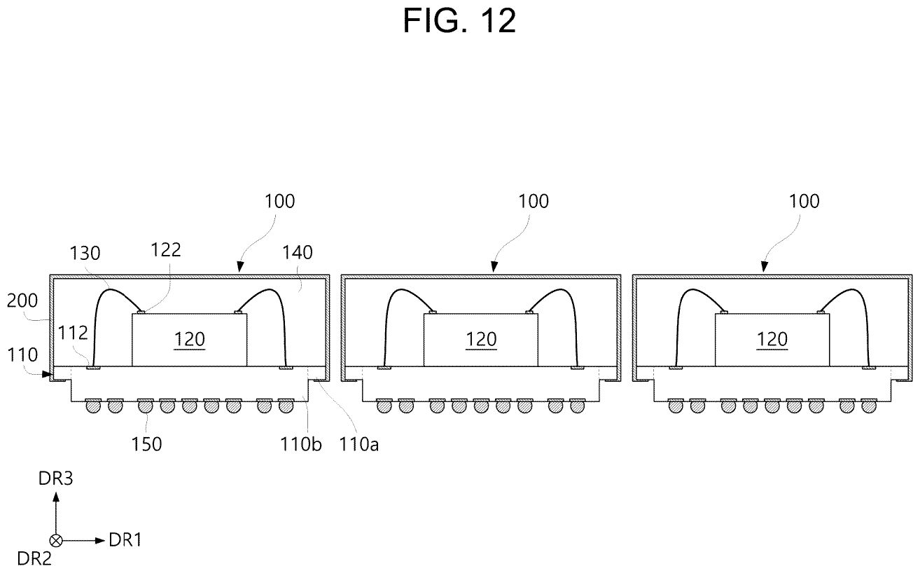

Referring to FIGS. 5 and 12, the semiconductor packages 100 may be separated from the carrier 300 (S160). When the shield 200 and the dummy shield 202 are connected in step S150, the dummy shield 202 may remain on the carrier 300 when the semiconductor packages 100 are separated from the carrier 300. When the shield 200 and the dummy shield 202 are connected, because the portion of the shield 200 on the side surface 110bs of the second substrate region 110b has a relatively thin thickness (third thickness T3 in FIG. 4B), the portion of the shield 200 that is on the side surface 110bs of the second substrate region 110b may be separated from the dummy shield 202 when the semiconductor packages 100 are separated from the carrier 300. Accordingly, the shield 200 may be formed to contact the surfaces of the mold 140 and the package substrate 110.

In a comparative example, when the package substrate has a uniform thickness throughout, the dummy shield may be separated together with the semiconductor package when separating the semiconductor package from the carrier. The separated semiconductor package may include the shield and the dummy shield. For example, after the semiconductor package is separated from the carrier, the dummy shield may remain attached to the semiconductor package instead of staying on the carrier. For example, the dummy shield may be spaced apart from the package substrate and connected to the shield. This may result in defects in the semiconductor package.

In the shield material deposition process, according to exemplary embodiments of the present inventive concept, the shield 200 and the dummy shield 202 may be spaced apart from each other, or the shield 200 may be connected to the dummy shield 202 through a thin portion. For example, in the situation where the shield 200 and the dummy shield 202 are connected to each other, the shield 200 and the dummy shield 202 may be connected to each other through a thin layer of deposited shield material. For example, the shield 200 may be formed with thinner portions below the first substrate region 110a to form a thin connection with the dummy shield 202. Accordingly, a method of manufacturing a semiconductor package 100, in which the dummy shield 202 remains on the carrier 300 when the semiconductor package 100 is separated from the carrier 300, may be provided.

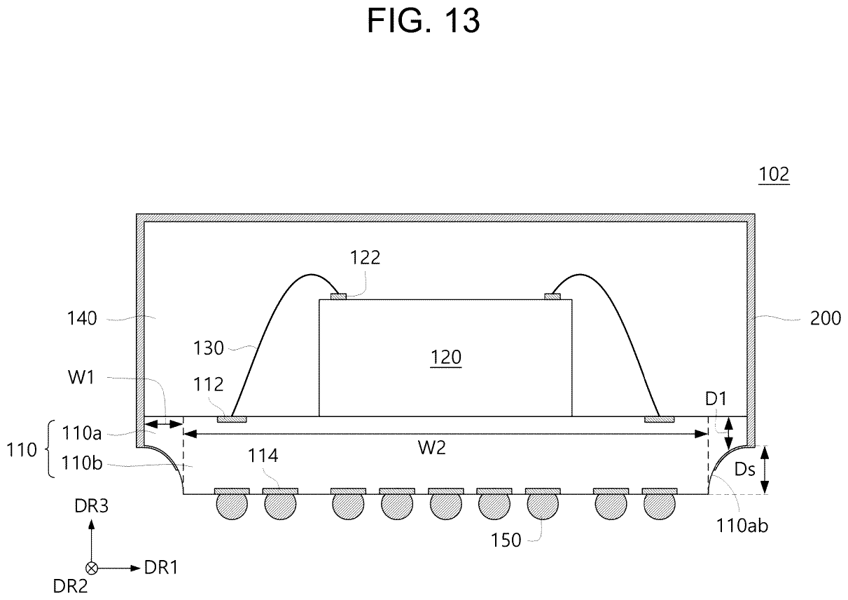

FIG. 13 is a cross-sectional view corresponding to line A-A′ of FIG. 1 showing a semiconductor package according to exemplary embodiments of the present inventive concept. For the sake of brevity, differences from what was described with reference to FIGS. 1 to 4C are explained.

Referring to FIG. 13, a semiconductor package 102 may be provided. Unlike what was described with reference to FIGS. 1 to 3, the first substrate thickness D1 of the first substrate region 110a may decrease as it gets farther from the second substrate region 110b. The first substrate width W1 of the first substrate region 110a may increase and then become constant along the third direction DR3. For example, the first substrate width W1 may extend along the first direction DR1 or the second direction DR2. The bottom surface of the first substrate region 110a may be curved. For example, the bottom surface of the first substrate region 110a may have a concave shape that protrudes toward an inner region of the package substrate 110. The lower side surface of the second substrate region 110b might not be exposed.

The shield 200 may be formed on the bottom surface 110ab of the first substrate region 110a. The thickness of the shield 200 on the bottom surface 110ab of the first substrate region 110a (i.e., the second shield thickness T2) may be smaller than the thickness of the shield 200 on the side surface 110as of the first substrate region 110a (i.e., the first shield thickness T1).

Exemplary embodiments of the present inventive concept can provide a semiconductor package 102 with a reduced defect rate.

According to exemplary embodiments of the present inventive concept, a semiconductor package with a decreased defect rate may be provided.

According to exemplary embodiments of the present inventive concept, a method for manufacturing a semiconductor package with a decreased defect rate may be provided.

While the present inventive concept has been particularly shown and described with reference to exemplary embodiments thereof, it will be apparent to those of ordinary skill in the art that various changes in form and detail may be made thereto without departing from the spirit and scope of the present inventive concept.

What is claimed is:

1. A semiconductor package comprising:
a package substrate including a first substrate region and a second substrate region, wherein the first substrate region at least partially surrounds the second substrate region;
a semiconductor chip disposed on the package substrate;
a mold provided on the package substrate and covering the semiconductor chip; and
a shield provided on the mold and the package substrate,
wherein a thickness of the first substrate region is smaller than a thickness of the second substrate region.

2. The semiconductor package of claim 1, wherein the shield extends along a side surface and a bottom surface of the first substrate region.

3. The semiconductor package of claim 2, wherein a thickness of the shield on the bottom surface of the first substrate region is smaller than a thickness of the shield on the side surface of the first substrate region.

4. The semiconductor package of claim 2, wherein the shield covers a first portion of the bottom surface of the first substrate region and exposes a second portion of the bottom surface of the first substrate region.

5. The semiconductor package of claim 1, wherein the shield extends along a side surface and a bottom surface of the first substrate region and a side surface of the second substrate region.

6. The semiconductor package of claim 5, wherein each of a thickness of the shield on the bottom surface of the first substrate region and a thickness of the shield on the side surface of the second substrate region is smaller than a thickness of the shield on the side surface of the first substrate region.

7. The semiconductor package of claim 6, wherein the thickness of the shield on the side surface of the second substrate region is smaller than the thickness of the shield on the bottom surface of the first substrate region.

8. The semiconductor package of claim 6, wherein the shield covers a first portion of the side surface of the second substrate region and exposes a second portion of the side surface of the second substrate region.

9. The semiconductor package of claim 1, wherein the thickness of the first substrate region is substantially uniform.

10. The semiconductor package of claim 1, wherein the thickness of the first substrate region decreases as it extends farther away from the second substrate region.

11. A semiconductor package comprising:
a package substrate including circuit pattern;
a semiconductor chip disposed on the package substrate;
bonding wires electrically connecting the semiconductor chip and the circuit pattern to each other;
a mold provided on the package substrate and covering the semiconductor chip and the bonding wires;
external connection terminals provided on the package substrate; and
a shield provided on the mold and the package substrate,
wherein the package substrate includes a first substrate region and a second substrate region, wherein the first substrate region has a first thickness, and the second substrate region has a second thickness that is greater than the first thickness, and
wherein the shield is disposed on a side surface and a bottom surface of the first substrate region, and wherein a thickness of the shield on the bottom surface of the first substrate region is smaller than a thickness of the shield on the side surface of the first substrate region.

12. The semiconductor package of claim 11, wherein the shield covers a first portion of the bottom surface of the first substrate region and does not cover a second portion of the bottom surface of the first substrate region.

13. The semiconductor package of claim 11, wherein the shield is disposed on a side surface of the second substrate region.

14. The semiconductor package of claim 13, wherein a thickness of the shield on the side surface of the second substrate region is smaller than the thickness of the shield on the side surface of the first substrate region.

15. The semiconductor package of claim 11, wherein the bottom surface of the first substrate region is curved.

16. A semiconductor package comprising:
a package substrate including a first substrate region and a second substrate region that is adjacent to the first substrate region, wherein a thickness of the first substrate region is less than a thickness of the second substrate region;
a semiconductor chip disposed on the package substrate; and
a shield disposed on the package substrate and covering the semiconductor chip, wherein shield extends along a side surface and a bottom surface of the first substrate region.

17. The semiconductor package of claim 16, wherein a thickness of the shield on the bottom surface of the first substrate region is smaller than a thickness of the shield on the side surface of the first substrate region.

18. The semiconductor package of claim 16, wherein the shield is disposed on a side surface of the second substrate region.

19. The semiconductor package of claim 18, wherein a thickness of the shield on the side surface of the second substrate region is substantially a same as a thickness of the shield on the bottom surface of the first substrate region.

20. The semiconductor package of claim 16, wherein the bottom surface of the first substrate region has a concave shape.
